(19) United States
(12) Patent Application Publication
(10) Pub. No.: US 2016/0148814 A1
(43) Pub. Date: May 26, 2016

(54) LIQUID TITANIUM OXIDE COMPOSITIONS, METHODS FOR FORMING THE SAME, AND METHODS FOR ETCHING MATERIAL LAYERS OF OR OVERLYING SUBSTRATES USING THE SAME

(71) Applicant: Honeywell International Inc., Morris Plains, NJ (US)

(72) Inventors: Helen X. Xu, Sunnyvale, CA (US); Richard Alan Spear, Santa Cruz, CA (US); Roger Y. Leung, San Jose, CA (US); Lea Marie Metin, San Jose, CA (US); Songyuan Xie, E. Palo Alto, CA (US); Zeyu Benjamin Wu, Cupertino, CA (US); Joseph Kennedy, San Jose, CA (US)

(21) Appl. No.: 14/896,272

(22) PCT Filed: Jun. 2, 2014
(86) PCT No.: PCT/US2014/040443

§ 371 Date: Dec. 4, 2015

Related U.S. Application Data
(60) Provisional application No. 61/831,843, filed on Jun. 6, 2013.

(51) Int. Cl. H01L 21/308; C09D 7/00

(52) U.S. Cl. CPC H01L 21/3081; C09D 7/001

(57) ABSTRACT

Liquid titanium oxide compositions, methods for forming such compositions, and methods for etching material layers using such compositions are provided. In accordance with an exemplary embodiment, a liquid titanium oxide composition contains a solvent system, an organotitanate, and a high boiling point solvent having a boiling point in the range of about 140° C. to about 400° C.

### CROSS-REFERENCE TO RELATED APPLICATIONS

This application claims the benefit of U.S. Provisional Application No. 61/831,843, filed Jun. 6, 2013.

### TECHNICAL FIELD

The technical field generally relates to metal oxide compositions, methods for forming the same, and methods for etching material layers of or overlying substrates using the same, and more particularly relates to liquid titanium oxide compositions, methods for forming the same, and methods for etching material layers of or overlying substrates using the same.

### BACKGROUND

Polymerized metal oxide films from metal alkoxides have been used in a variety of applications. In the semiconductor industry, titanium oxide has become a preferred system for use as an etch mask for several reasons. Titanium oxide films demonstrate a significant advantage on etch selectivity over silicon oxide films in terms of typical fluorocarbon-based chemistry plasma etch rates. Titanium oxide sol-gels also can be formed at low temperatures, even at room temperature. In addition, titanium oxide etches rapidly in peroxide and hydrofluoric acid chemistries providing a high degree of removal selectivity to other exposed films. This selectivity promotes critical dimension control, even as the scaling of semiconductor device features continues.

However, conventional titanium oxide compositions exhibit several challenges. The formation of a titanium oxide etch mask generally involves the spin-coating of a liquid titanium oxide composition in sol-gel form over a semiconductor wafer. This process often results in unwanted titanium oxide residue on the backside of the wafer. Such surface tension-induced wraparound of the cast material is common in the spin-on polymer industry and is termed “back-side residue.” This backside residue is most often located at the outer perimeter of the wafer backside. It is important to remove this residue by a cleaning solvent rinse (termed “backside rinse,” typically applied in the latter stage of the spin coat process) to avoid contamination of downstream tool sets. However, current backside rinses, such as propylene glycol methyl ether acetate (PGMEA), methyl isobutyl carbinol (MIBC), acetone, and others, may only partially remove such backside titanium oxide residue. In addition to being removable by cleaning solvents, the titanium oxide composition, once deposited on a semiconductor wafer, and optionally baked, should remain resistant to these solvents as well as other chemistries used in the integrated circuit industry, and more specifically in lithography such as photoresist casting solvents and photoresist developers, such as, for example, 2.3% aqueous tetramethylammonium hydroxide (TMAH).

Accordingly, it is desirable to provide a liquid titanium oxide composition that is easily removed by cleaning solvents during backside rinse and, when baked at a temperature above a preset temperature, is resistant to these solvent rinses and in addition to photoresist developers. In addition, it is desirable to provide methods for forming such liquid titanium oxide compositions. It also is desirable to provide methods for etching material layers of or overlying substrates using such liquid titanium oxide compositions. Furthermore, other desirable features and characteristics of the various embodiments will become apparent from the subsequent detailed description and the appended claims, taken in conjunction with the accompanying drawings and this background.

### BRIEF SUMMARY

Liquid titanium oxide compositions, methods for forming such compositions, and methods for etching material layers of or overlying substrates using such compositions are provided. In accordance with an exemplary embodiment, a liquid titanium oxide composition contains a solvent system, an organotitanate, and a high boiling point solvent having a boiling point in the range of about 140° C. to about 400° C.

In accordance with another exemplary embodiment, a liquid composition includes an organotitanate of a formula: Ti(OR)₄, where each R can be different and R is an alkyl radical having 1 to 6 carbons or R is an alkylene oxide. The liquid composition further includes an alcohol, a composition stabilizer, and a high boiling point solvent having a boiling point in a range of about 140° C. to about 400° C. The liquid composition, once deposited on a substrate and cured to form a cured film, comprises titanium in an amount of about 25 to about 55 wt. % based on a total weight of the cured film.

A method for forming a liquid titanium oxide system in accordance with an exemplary embodiment also is provided. The method includes adding an organotitanate to a solvent system to form a mixture. The organotitanate has the formula: Ti(OR)₄, where each R can be different and R is an alkyl radical having 1 to 6 carbons or R is an alkylene oxide. A high boiling point solvent is added to the mixture. The high boiling point solvent has a boiling point in the range of from about 140° C. to about 400° C.

A method of etching a material layer of or overlying a substrate in accordance with an exemplary embodiment is further provided. The method includes providing a titanium oxide composition. The composition contains a solvent system, an organotitanate, and a high boiling point solvent having a boiling point in a range of about 140° C. to about 400° C. The method also includes depositing the titanium oxide composition overlying the material layer. Residue of the titanium oxide composition is cleaned from a back side of the substrate using a cleaning solvent rinse. The titanium oxide composition is baked and patterned to produce a patterned mask and the material layer is etched using the patterned mask.

### DETAILED DESCRIPTION

The following detailed description is merely exemplary in nature and is not intended to limit the various embodiments or the application and uses thereof. Furthermore, there is no intention to be bound by any theory presented in the preceding background or the following detailed description.

In accordance with various embodiments, a liquid titanium oxide composition is provided. The titanium oxide composition is suitable for use as an etch mask in semiconductor processing. In addition, the titanium oxide composition can be used for other applications such as, for example, an antireflective coating. In one embodiment, the titanium oxide composition is formed such that cross-linking during formation of the titanium oxide composition is inhibited. In this regard, the liquid titanium oxide composition may be formed without water. In addition, or alternatively, the composition may be formed substantially without acid. In addition or alternatively, the composition may include a composition stabilizer. In another embodiment, the titanium oxide composition comprises a high boiling point solvent that has a boiling point in the range of from about 140° C. to about 400° C. As described in more detail below, the high boiling point solvent increases the onset insolubility temperature such that the titanium oxide composition is more soluble in a backside rinse cleaning solvent used to remove titanium oxide residue, for example, on the perimeter of the backside of the wafer.

In accordance with an exemplary embodiment, the liquid titanium oxide composition contains an organotitanate. As used herein, “organotitanate” means titanium- and oxygen-containing organic materials that can include polymeric, non-polymeric, or semi-polymeric forms, including polymeric precursors. Organotitanates useful herein are formed from titanium organo-oxides of the formula Ti(OR)₄, where R is an alkyl radical having 1 to 6 carbons or R is an alkylene oxide and the four R′s of the formula are not necessarily the same. Examples of suitable organotitanates include tetraisopropyl titanate (TIPO), tetraethyl titanate, tetrapropyl titanate, tetrabutyl titanate, tetraisobutyl titranate, tetra-tert-butyl titanate, tetrahexyl titanate, titanium (polyethylene oxide) triisopropoxide, titanium diisopropoxide (bis-2,4-pentanedionate), and mixtures thereof In addition, the organotitanates can be titanium alkoxides and titanium-oxygen backbone polymers. The titanium-oxygen backbone polymers can have hydroxy and/or alkoxy and/or acetonate pendant groups and/or can have a molecular weight in the range of from about 200 to about 10 million Daltons.

The liquid titanium oxide composition also comprises a solvent system. Optimum solvents are selected on several criteria ranging from film coat quality, flashpoint, viscosity, and shelf life stability of the composition. In an exemplary embodiment, the solvent system includes one or more alcohols. Suitable alcohols for use in the solvent system can be any liquid alcohol that is a solvent for organotitanate. Exemplary alcohols include, but are not limited to, methanol, ethanol, n-propanol, i-propanol, n-butanol, i-butanol, t-butanol, sec-butanol, 1-propoxy-2-propanol, PGME, ethylene glycol, propylene glycol, and the like, and mixtures thereof The solvent system also may include other components that act as solvents for organotitanates, such as ethers, esters, aldehydes, carboxylic acids, glycol ethers, polyglycol ethers, fluorinated alkanes, chlorinated alkanes, and mixtures thereof.

In another embodiment, the solvent system contains water, for example, deionized water, in addition to the alcohol. The water is present in an amount such that only partial hydrolysis occurs. For example, water may be present in a water:total alcohol ratio of from about 1:55 to about 1:167. In addition or alternatively, the water may be present in an amount of 0.05 to about 3.0 moles/moles of titanium in the organotitanate.

In an alternative embodiment, the spin-on liquid titanium oxide composition contains substantially no water. As used herein, the term “substantially no water” means having no water or such an amount of water that the physical, chemical, and/or rheological properties of the liquid titanium oxide composition are not identifiably or measurably changed by the addition of the water. For example, “substantially no water” can mean having less than about 0.1 wt. % water based on the total weight of the liquid titanium oxide composition. With substantially no water, polymerization of the organotitanate essentially does not occur upon mixing of the organotitanate and the solvent. Rather, cross-linking begins to occur when the liquid titanium oxide composition is spun onto a substrate, at which point the composition is exposed to ambient moisture. This ambient moisture may result in some hydrolysis and polycondensation and, thus, some cross-linking of the organotitanate, which is limited by the amount of moisture in the atmosphere. The humidity within spin coater systems is well controlled and typically ranges from about 35 to about 45% humidity. The amount of moisture in the ambient environment is usually significantly less than that typically added to an organotitanate during conventional polymerization of the organotitanate. In this regard, cross-linking is minimized, resulting in a liquid titanium oxide composition that, once spun onto a substrate, is significantly easier to remove by a cleaning solvent than a liquid titanium oxide composition with water added during formation of the composition.

In another embodiment, the liquid titanium composition contains a chelating agent. The chelating agent stabilizes the composition by inhibiting polymerization during and/or after formation of the composition, thus extending the useful (e.g., shelf) life of the composition. Examples of suitable chelating agents include acetic acid, trichloroacetic acid, oleic acid, 2,4-pentanedione, and the like, and mixtures thereof. In an embodiment, the chelating agent is added to the composition in an amount of from about zero to about 10 wt. % based on the total weight of the composition.

The liquid titanium composition further includes a catalyst in accordance with an embodiment. The catalyst prevents precipitation and self-condensation that would normally occur during hydrolysis of the organotitanate in alkaline conditions. An example of a suitable catalyst for use herein is nitric acid, although other suitable catalysts could also be used. In an embodiment, the catalyst is added to the compositions in an amount of from about 0.01 wt. % to about 2.0 wt. % based on the total weight of the composition.

In an alternative embodiment, the composition contemplated herein contains substantially no acid. As used herein, the term “substantially no acid” means having no acid or such an amount of acid that the physical, chemical, and/or rheological properties of the liquid titanium oxide composition are not identifiably or measurably changed by the addition of the acid. For example, “substantially no acid” can mean having less than about 0.01 wt. % acid based on the total weight of the liquid titanium oxide composition. In another embodiment, the pH of the liquid titanium oxide composition is no greater than 7. In the absence of acid, or when the pH of the composition is no greater than 7, cross-linking is inhibited during formation of the liquid titanium oxide composition. As with the absence of water, this results in a liquid titanium oxide composition that, once spun onto a substrate, is significantly easier to remove by a cleaning solvent than a liquid titanium oxide composition with acid or a liquid titanium oxide composition with a pH greater than 7.

In another embodiment, the liquid titanium oxide composition has a cross-linking inhibitor and stabilizer (hereinafter referred to as a “composition stabilizer”). The composition stabilizer facilitates kinetic control of the hydrolysis and condensation during formation of the composition, thus providing control of the polymerization reaction. In this regard, the cross-linking of the composition is less with the composition stabilizer than without it and the composition is easier to remove using a cleaning solvent. Composition stabilizers suitable for use herein include, but are not limited to 2,4-pentanedione, 3,3-dimethyl-2,4-pentanedione, 3-methy-2,4-pentanedione ethylacetoacetate, diethyl malonate, diethyl malate, ethylene diamine tetra-acetic acid, oxalic acid, oxamic acid, octanoic acid, oleic acid, dodecylcarboxylic acid, perfluorooctanoic acid, ethyl lactate, butylated hydroxytoluene, 1,3-propane diol, and mixtures thereof The composition stabilizer is present in an amount that does not significantly reduce the amount of titanium in the composition but is sufficient to inhibit cross-linking of the organotitanate such that spun-on composition residue is easier to remove. In an embodiment, the composition stabilizer is present in an amount of about 4 to about 32 moles/moles titanium, for example, about 8 mol/mol titanium.

The liquid titanium oxide composition further contains a high boiling point solvent. As used herein, the term “high boiling point solvent” means a solvent that is miscible in the solvent system described above and has a boiling point in the range of about 140° C. to about 400° C. High boiling point solvents with boiling points above 400° C. require higher baking temperatures during formation of the etch mask, which depending on the thermal properties of the underlying film(s) may or may not lead to integration issues. In one embodiment, the high boiling point solvents have a viscosity no greater than about 15 centipoise (cP), for example, no greater than about 10 cP. Examples of suitable high boiling point solvents include, but are not limited to, tripropylene glycol methyl ether, available from the Dow Chemical Company of Midland, Michigan, as Dowanol® TPM with a boiling point of 243° C., dipropylene glycol n-propyl ether, available from the Dow Chemical Company as Dowanol® DPnP with a boiling point of 213° C., dipropylene glycol butyl ether, available from the Dow Chemical Company as Dowanol® DPnB with a boiling point of 230° C., tripropylene glycol n-butyl ether, available from the Dow Chemical Company as Dowanol® TPnB with a boiling point of 275° C., carbitol, hexyl carbitol, methoxytriglycol, methyl carbitol, butyl cellosolve, butyl cellosolve acetate, butyl carbitol acetate, diethylene glycol phenyl ether, and mixtures thereof In an embodiment, the high boiling point solvent is present in the titanium oxide composition in an amount of about 0.5 wt. % to about 95 wt. % based on the total weight of the composition. The amount of the high boiling point solvent can be limited by the viscosity of the final composition and the effects a more viscous composition as well as a more slowly evaporating composition may have on the quality of the cast film. In one exemplary embodiment, once formed, the resulting titanium oxide composition has a viscosity is no greater than 5 cP.

It has been found that the addition of a high boiling point solvent increases the onset insolubility temperature of the resulting liquid titanium oxide composition, once deposited onto a substrate and optionally baked. The “onset insolubility temperature” is the lowest baking temperature at which a material cannot be removed from a substrate using a solvent. Generally, for purposes herein, the onset insolubility temperature is determined by dispensing a metal oxide composition onto a substrate, such as a semiconductor wafer, for about 4 seconds. The substrate is spun at 1500 rotations per minute (RPM) for twenty seconds to obtain a 200-300 angstrom thick coating, depending on the solvents used in the composition. (Thicker compositions may warrant thicker coatings.) The substrate is then held at zero RPM for 2 minutes. A test cleaning removal solvent, for example, PGMEA at room temperature, is dispensed onto the metal oxide composition coating for 0.5 seconds, and the solvent is then spun off at 1500 RPM for 20 seconds. If substantially all of the coating is removed with no baking, the procedure can be rerun such that, after the substrate is spun at 1500 RPM for 20 seconds, the metal oxide composition is baked at a desired temperature for a period of time such as 60 seconds. The baked metal oxide composition coating is cooled, the cleaning solvent rinse is dispensed for 4 seconds, and then spun off the coating at 1500 RPM for 20 sec. With or without baking, the coating thickness is measured at three different locations. If the coating has been removed by the solvent, that is, if the solvent is able to remove 100 angstroms or more of the coating, the process is repeated with the baking temperature increased. The onset insolubility temperature is determined to be the temperature at which the coating was baked or, if not baked, room temperature, and the solvent was not able to remove the coating by about 100 angstroms or more. With regard to the liquid titanium oxide composition, the higher the onset insolubility temperature, the easier it is to remove the spun-on composition with a removal solvent, such as PGMEA, during a backside rinse process. The addition of a composition stabilizer, the absence of water, and/or the absence of acid in addition to use of the high boiling point solvent used to fabricate the liquid titanium oxide composition further serve to reduce cross-linking and raise the onset insolubility temperature of the composition such that the composition is easier to remove than if the composition was formed without such effects. It has been found that the liquid titanium oxide composition with such an increased onset insolubility temperature still maintains resistance to chemistries such as photoresist developer, such as 2.3% aqueous TMAH, when baked to a temperature higher than the onset insolubility temperature.

In another embodiment, a method for forming a liquid titanium oxide composition includes adding an organotitanate to a solvent system. As noted above, the solvent system may contain an alcohol. Any of the alcohols identified above with respect to the solvent system can be used. In another embodiment, the solvent system contains an alcohol and water. As noted above, the water may be present in a water:total alcohol ratio of from about 1:55 to about 1:167. In addition or alternatively, the water may be present in an amount of 0.5 to 3 moles/moles organotitanate. The solvent system may also contain ethers, esters, aldehydes, carboxylic acids, glycol ethers, polyglycol ethers, fluorinated alkanes, chlorinated alkanes, and mixtures thereof. The organotitanate can be any of the organotitanate described above having the formula Ti(OR)₄, where R is an alkyl radical having 1 to 6 carbons. The organotitanate is added drop-wise into the solvent system over a thirty to sixty minute period while the solvent system is vigorously stirred. The temperature of the solvent system is monitored during addition of the organotitanate to ensure the system remains below 30° C. In an embodiment, the resulting solution is vigorously stirred for period of time, such as about two hours, to allow the solution to stabilize and to allow any reactions to conclude.

In an optional embodiment, a chelating agent and/or a catalyst are added to the solution after addition of all the organotitanate. The chelating agent and catalyst can be any of the chelating agents and catalysts described above. In another embodiment, the solution with the catalyst and/or chelating agent is stirred for a period of time, such as, for example, 8 to 12 hours. Without wishing to be bound by theory, it is believed that such a period of time is useful to allow the solution to stabilize.

Next, the solution is diluted such that the liquid titanium oxide composition, once spun on a substrate and baked, will result in a desired coating thickness. Any of the alcohols identified above for use in the solvent system are useful as a diluent to dilute the solution. In an exemplary embodiment, the diluent may be added in an amount 3 to 4 times the amount of alcohol in the solvent system.

In an embodiment, once the solution is diluted, a composition stabilizer is added to the solution. Any of the composition stabilizers described above can be utilized. The solution is stirred at room temperature during addition of the composition stabilizer to obtain a molecularly uniform solution. In an alternative embodiment, the composition stabilizer is added before or with the addition of the diluent.

In a further embodiment, a high boiling point solvent is added to the solution. The high boiling point solvent, as defined above, can be any of the high boiling point solvents identified above. The solution is mixed thoroughly for a period of time, for example, one hour. Next, the solution is filtered before use. A filter of at least 0.1 microns, for example, and for example less than 50 nm, is suitable for use. While as set forth above the composition stabilizer is described as being added before the high boiling point solvent, the alternative is also possible, and the high boiling point solvent can be added to the solution before the composition stabilizer, if used, is added.

A method for etching a material layer of or overlying a substrate is provided in another embodiment. The method includes providing a titanium oxide composition. Any of the titanium oxide compositions described above with respect to any of the various embodiments contemplated herein can be utilized. The titanium oxide composition is deposited overlying a material layer to be etched. In one embodiment, the material layer overlies the substrate. As used herein, the term “overlies” means that the material layer lies on the substrate or lies over the substrate such that intervening layers are disposed between the material layer and the substrate. In another embodiment, the material layer is of the substrate, that is, the material layer is integral with the substrate. The material layer can be, for example, a dielectric, a metal, a semiconductor material, or any other material used in the semiconductor industry and subjected to patterning and etching processes. The titanium oxide deposition is deposited on the material layer using any conventional application process, such as, for example, spin-coating, screen printing, roller printing, or the like.

During deposition, residue of the titanium oxide composition can deposit on the back side of the substrate, such as on the perimeter of the substrate. It is desirable to remove this residue so that it does not contaminate downstream tool sets. In this regard, in an embodiment, the residue of the titanium oxide composition next is cleaned from the back side of the substrate and, optionally, the perimeter edge of the substrate, using a cleaning solvent rinse. Any of the cleaning solvents described herein can be used.

Once the residue is removed, the titanium oxide composition is cured. In one embodiment, the titanium oxide composition is exposed to the ambient atmosphere to allow volatile species to evaporate, thus forming a cured film. In an optional embodiment, the titanium oxide composition is baked at a temperature above ambient temperature to cure the composition. The titanium oxide composition can be baked at an oven temperature in the range of, for example, about 100 to about 700° C., for example, from about 100 to about 500° C. In an embodiment, once cured, whether by exposure to the ambient or baked, the cured film has a titanium concentration in the range of from about 16 to about 60 wt. %, for example, from about 25 to about 55 wt. %, based on a wt. % of the total cured film.

Once the residue is removed, the titanium oxide composition is patterned to produce a patterned mask. In this regard, conventional photolithographic processing can be used. The material layer is then etched using the patterned mask. The material layer is etched using an etchant that etches the material layer faster than it etches the cured titanium oxide composition.

The following are examples of liquid titanium oxide compositions and methods for forming them. The examples are provided for illustration purposes only and are not meant to limit the various embodiments in any way.

### EXAMPLE 1

Approximately 300 g of 1-propoxy-2-propanol, 5.4 g of deionized water, and 0.2 g nitric acid were added to a round bottom flask and stirred at room temperature. 42.75g of tetraisopropoxytitanium (IV) was added to an addition funnel affixed to the flask containing the solvent system. The tetraisopropoxytitanium (IV) was allowed to drip into the solvent system for thirty minutes while the solvent system was vigorously stirred. The temperature of the mixture was monitored and maintained below 30° C. The solution was stirred for two hours. Approximately 0.45 g acetic acid then was added to the solution during vigorous stirring. The solution was allowed to sit overnight. Next, 45.06 g of the solution was diluted with 164.92 g of 1-propoxy-2-propanol to obtain a titanium oxide composition that would result in a 15 nm coating after spin-coating and optional baking. The solution was mixed thoroughly for one hour, and was filtered with a 0.1 micron filter, resulting in a titanium oxide composition “Example 1.” Example 1 was found to be resistant to TMAH at room temperature when spin coated onto a semiconductor wafer and baked at 200° C. for sixty seconds in nitrogen gas.

### EXAMPLE 2

Approximately 1200.4 g of 1-propoxy-2-propanol, 21.6 g of deionized water and 0.83g of 70% nitric acid were added to a round bottom flask and stirred at room temperature. 170.53g of tetraisopropoxytitanium (IV) was added to an addition funnel affixed to the flask containing the solvent system. The tetraisopropoxytitanium (IV) was allowed to drip into the solvent system for thirty minutes while the solvent system was vigorously stirred. The temperature of the solution was monitored and maintained below 30° C. Two hours after the addition was complete 1.8g of acetic acid was added during stirring. The solution was allowed to stir overnight. To the solution, 4.78 g of 2,4-pentanedione was added. Next, 45.06 g of the solution was diluted with 162.216 g of 1-propoxy-2-propanol to obtain a titanium oxide composition that would result in a 15 nm coating after spin-coating and optional baking. The solution was mixed thoroughly for one hour, and was filtered with a 0.1 micron filter, resulting in a titanium oxide composition “Example 2,” that is, Example 1 with a composition stabilizer. Example 2 was found to be resistant to TMAH at room temperature when spin coated onto a semiconductor wafer and baked at 200° C. for sixty seconds in nitrogen gas.

### EXAMPLE 3

Approximately 300 g of 1-propoxy-2-propanol, 5.4 g of deionized water, and 0.2 g nitric acid were added to a round bottom flask and stirred at room temperature. 42.75 g of tetraisopropoxytitanium (IV) was added to an addition funnel affixed to the flask containing the solvent system. The tetraisopropoxytitanium (IV) was allowed to drip into the solvent system for thirty minutes while the solvent system was vigorously stirred. The temperature of the solution was monitored and maintained below 30° C. The solution was stirred for two hours. Approximately 0.45 g acetic acid then was added to the solution during vigorous stirring. The solution was allowed to sit overnight. Next, 45.06 g of the solution was diluted with 123.69 g of 1-propoxy-2-propanol and 41.23 g of TPnB to obtain a titanium oxide composition that would result in a 15 nm coating after spin-coating and optional baking. The solution was mixed thoroughly for one hour, and was filtered with a 0.1 micron filter, resulting in a titanium oxide composition “Example 1+20% TPnB.” This composition was found to be resistant to TMAH at room temperature when spin coated onto a semiconductor wafer and baked at 200° C. for sixty seconds in nitrogen gas.

### EXAMPLE 4

Approximately 300 g of 1-propoxy-2-propanol, 5.4 g of deionized water, and 0.2 g nitric acid were added to a round bottom flask and stirred at room temperature. 42.75 g of tetraisopropoxytitanium (IV) was added to an addition funnel affixed to the flask containing the solvent system. The tetraisopropoxytitanium (IV) was allowed to drip into the solvent system for thirty minutes while the solvent system was vigorously stirred. The temperature of the solution was monitored and maintained below 30° C. The solution was stirred for two hours. Approximately 0.45 g acetic acid then was added to the solution during vigorous stirring. The solution was allowed to sit overnight. To the solution, 1.2 g 2,4-pentanedione was added. Next, 45.06 g of the solution was diluted with 123.69 g of 1-propoxy-2-propanol and 41.23 g of TPnB to obtain a titanium oxide composition that would result in a 15 nm coating after spin-coating and optional baking. The solution was mixed thoroughly for one hour, and was filtered with a 0.1 micron filter, resulting in a titanium oxide composition “Example 2+20% TPnB.” Example 2+20% TPnB was found to be resistant to TMAH at room temperature when spin coated onto a semiconductor wafer and baked at 200° C. for sixty seconds in nitrogen gas.

### EXAMPLE 5

Approximately 300 g of 1-propoxy-2-propanol was added to a round bottom flask and stirred at room temperature. 42.75 g of tetraisopropoxytitanium (IV) was added to an addition funnel affixed to the flask containing the solvent system. The tetraisopropoxytitanium (IV) was allowed to drip into the solvent system for thirty minutes while the solvent system was vigorously stirred. The temperature of the solution was monitored and maintained below 30° C. The solution was allowed to stir overnight. To the solution, 1.2 g of 2,4-pentanedione was added. Next 45.06 g of the solution was diluted with 159.97 g of 1-propoxy-2-propanol and 4.95g of TPnB to obtain a titanium oxide composition that would result in a 15 nm coating after spin-coating and optional baking. The solution was mixed thoroughly for one hour, and was filtered with a 0.1 micron filter, resulting in a titanium oxide composition “Example 2−no acid−no water+3% TPnB.”

### EXAMPLE 6

Approximately 300 g of 1-propoxy-2-propanol was added to a round bottom flask and stirred at room temperature. 42.75 g of tetraisopropoxytitanium (IV) was added to an addition funnel affixed to the flask containing the solvent system. The tetraisopropoxytitanium (IV) was allowed to drip into the solvent system for thirty minutes while the solvent system was vigorously stirred. The temperature of the solution was monitored and maintained below 30° C. The solution was stirred for two hours. Approximately 0.45 g acetic acid was added to the solution during vigorous stirring. The solution was allowed to stir overnight. To the solution, 1.2 g of 2,4-pentanedione was added. Next 45.06 g of the solution was diluted with 159.97 g of 1-propoxy-2-propanol and 4.95 g of TPnB to obtain a titanium oxide composition that would result in a 15 nm coating after spin-coating and optional baking. The solution was mixed thoroughly for one hour, and was filtered with a 0.1 micron filter, resulting in a titanium oxide composition “Example 2-no water+acetic acid+3% TPnB.”

### EXAMPLE 7

Approximately 300 g of 1-propoxy-2-propanol, 5.4 g of deionized water, and 0.2 g nitric acid were added to a round bottom flask and stirred at room temperature. 42.75 g of tetraisopropoxytitanium (IV) was added to an addition funnel affixed to the flask containing the solvent system. The tetraisopropoxytitanium (IV) was allowed to drip into the solvent system for thirty minutes while the solvent system was vigorously stirred. The temperature of the solution was monitored and maintained below 30° C. The solution was stirred for two hours. Approximately 0.45 g acetic acid then was added to the solution during vigorous stirring. The solution was allowed to sit overnight. To the solution, 1.2 g of 2,4-pentanedione was added. Next, 45.06 g of the solution was diluted with 159.97 g of 1-propoxy-2-propanol and 4.95 g of TPnB to obtain a titanium oxide composition that would result in a 15 nm coating after spin-coating and optional baking. The solution was mixed thoroughly for one hour, and was filtered with a 0.1 micron filter, resulting in a titanium oxide composition “Example 2+3% TPnB.” Example 2+3% TPnB was found to be resistant to TMAH at room temperature when spin coated onto a semiconductor wafer and baked at 200° C. for sixty seconds in nitrogen gas.

### EXAMPLE 8

Approximately 300 g of 1-propoxy-2-propanol and 5.4 g of deionized water were added to a round bottom flask and stirred at room temperature. 42.75 g of tetraisopropoxytitanium (IV) was added to an addition funnel affixed to the flask containing the solvent system. The tetraisopropoxytitanium (IV) was allowed to drip into the solvent system for thirty minutes while the solvent system was vigorously stirred. The temperature of the solution was monitored and maintained below 30° C. The solution was allowed to sit overnight. To the solution, 1.2 g of 2,4-pentanedione was added. Next, 45.06 g of the solution was diluted with 159.97 g of 1-propoxy-2-propanol and 4.95 g of TPnB to obtain a titanium oxide composition that would result in a 15 nm coating after spin-coating and optional baking. The solution was mixed thoroughly for one hour, and was filtered with a 0.1 micron filter, resulting in a titanium oxide composition “Example 2-no acid+3% TPnB.” “Example 2-no acid+3% TPnB” was found to be resistant to TMAH at room temperature when spin coated onto a semiconductor wafer and baked at 200° C. for sixty seconds in nitrogen gas.

### EXAMPLE 9

Approximately 300 g of 1-propoxy-2-propanol was added to a round bottom flask and stirred at room temperature. 42.75 g of tetraisopropoxytitanium (IV) was added to an addition funnel affixed to the flask containing the solvent system. The tetraisopropoxytitanium (IV) was allowed to drip into the solvent system for thirty minutes while the solvent system was vigorously stirred. The temperature of the mixture was monitored and maintained below 30° C. The solution was stirred for two hours. Approximately 0.45 g acetic acid then was added to the solution during vigorous stirring. The solution was allowed to sit overnight. Next, 45.06 g of the solution was diluted with 164.92 g of 1-propoxy-2-propanol to obtain a titanium oxide composition that would result in a 15 nm coating after spin-coating and optional baking. The solution was mixed thoroughly for one hour, and was filtered with a 0.1 micron filter, resulting in a titanium oxide composition “Example 1−no water−no nitric acid.” Example 1−no water−no nitric acid was found to be resistant to TMAH at room temperature when spin coated onto a semiconductor wafer and baked at 200° C. for sixty seconds in nitrogen gas.

### EXAMPLE 10

Approximately 300 g of 1-propoxy-2-propanol was added to a round bottom flask and stirred at room temperature. 42.75 g of tetraisopropoxytitanium (IV) was added to an addition funnel affixed to the flask containing the solvent system. The tetraisopropoxytitanium (IV) was allowed to drip into the solvent system for thirty minutes while the solvent system was vigorously stirred. The temperature of the mixture was monitored and maintained below 30° C. The solution was stirred for two hours. Approximately 0.45 g acetic acid then was added to the solution during vigorous stirring. The solution was allowed to sit overnight. Next, 45.06 g of the solution was diluted with 164.92 g of 1-propoxy-2-propanol and tripropylene glycol methyl ether to obtain a titanium oxide composition that would result in a 15 nm coating after spin-coating and optional baking. The solution was mixed thoroughly for one hour, and was filtered with a 0.1 micron filter, resulting in a titanium oxide composition “Example 1−no water−no nitric acid+20 % TPM.” Example 1−no water−no nitric acid+20% TPM was found to be resistant to TMAH at room temperature when spin coated onto a semiconductor wafer and baked at 200° C. for sixty seconds in nitrogen gas.

### EXAMPLE 11

Approximately 300 g of 1-propoxy-2-propanol, 5.4 g of deionized water, and 0.2 g nitric acid were added to a round bottom flask and stirred at room temperature. 42.75 g of tetraisopropoxytitanium (IV) was added to an addition funnel affixed to the flask containing the solvent system. The tetraisopropoxytitanium (IV) was allowed to drip into the solvent system for thirty minutes while the solvent system was vigorously stirred. The temperature of the solution was monitored and maintained below 30° C. The solution was stirred for two hours. Approximately 0.45 g acetic acid then was added to the solution during vigorous stirring. The solution was allowed to sit overnight. To the solution, 1.2 g 2,4-pentanedione was added. Next, 45.06 g of the solution was diluted with 162.89 g of 1-propoxy-2-propanol and 54.29 g of TPnB to obtain a titanium oxide composition that would result in a 15 nm coating after spin-coating and optional baking. The solution was mixed thoroughly for one hour, and was filtered with a 0.1 micron filter, resulting in a titanium oxide composition “Example 2+25% TPnB.”

### EXAMPLE 12

Approximately 300 g of 1-propoxy-2-propanol and 2.4 g of 2,4-pentanedione was added to a round bottom flask and stirred at room temperature. 42.75 g of tetraisopropoxytitanium (IV) was added to an addition funnel affixed to the flask containing the solvent system. The tetraisopropoxytitanium (IV) was allowed to drip into the solvent system for thirty minutes while the solvent system was vigorously stirred. The temperature of the solution was monitored and maintained below 30° C. The solution was allowed to stir overnight. Next, 45.06 g of the solution was diluted with 162.22 g of 1-propoxy-2-propanol and 54.07 g of DPnP to obtain a titanium oxide composition that would result in a 13 nm coating after spin-coating and optional baking. The solution was mixed thoroughly for one hour, and was filtered with a 0.1 micron filter, resulting in a titanium oxide composition “Example 2−no acid-no water+16% Acac+25% DPnP.”

### EXAMPLE 13

Approximately 300 g of 1-propoxy-2-propanol and 9.6 g of 2,4-pentanedione was added to a round bottom flask and stirred at room temperature. 42.75 g of tetraisopropoxytitanium (IV) was added to an addition funnel affixed to the flask containing the solvent system. The tetraisopropoxytitanium (IV) was allowed to drip into the solvent system for thirty minutes while the solvent system was vigorously stirred. The temperature of the solution was monitored and maintained below 30° C. The solution was allowed to stir overnight. Next, 45.06 g of the solution was diluted with 162.22 g of 1-propoxy-2-propanol and 54.07 g of DPnP to obtain a titanium oxide composition that would result in a 13 nm coating after spin-coating and optional baking. The solution was mixed thoroughly for one hour, and was filtered with a 0.1 micron filter, resulting in a titanium oxide composition “Example 2−no acid-no water+64% Acac+25% DPnP.”

The Tables below show the effect on onset insolubility temperature of the various embodiments of the liquid titanium oxide compositions contemplated herein. All of the coatings were deposited using the procedure set forth above for determining onset insolubility temperature and were deposited to a thickness of 300 angstroms. Measurements above 300 angstroms were aberrant measurements. Measurements were taken using a three-point probe. Measurements of films with less than 50 angstroms thickness are considered to be removed films.

TABLE 1

| | 1500 RPM 20 sec | | | | | | | |
|---|---|---|---|---|---|---|---|---|
| | | | Time wait | | Thickness (angstroms) | | | |
| | | Bake | before cleaning | | Site | Site | Site | |
| Slot | Material | Temperature | solvent rinse | Solvent | 1 | 2 | 3 | Average |
| 1 | Example 1 | No Bake | 2 min | PGMEA | 252 | 249 | 238 | 246 |
| 2 | | | | Acetone | 250 | 247 | 246 | 248 |

As can be seen from Table 1, there is little removal of the titanium oxide composition Example 1 using either of the cleaning solvents.

TABLE 2

| | 1500 RPM 20 sec | | | | | | | |
|---|---|---|---|---|---|---|---|---|
| | | | Time wait | | Thickness (angstroms) | | | |
| | | Bake | before cleaning | | Site | Site | Site | |
| Slot | Material | Temperature | solvent rinse | Solvent | 1 | 2 | 3 | Average |
| 1 | Example 2 | No Bake | 2 min | PGMEA | 254 | 252 | 258 | 255 |

As can be seen from Table 2, there is little removal of the titanium oxide composition Example 2 using PGMEA.

TABLE 3

| | 1500 RPM 20 sec | | | | | | | |
|---|---|---|---|---|---|---|---|---|
| | | | Time wait | | Thickness (angstroms) | | | |
| | | Bake | before cleaning | | Site | Site | Site | |
| Slot | Material | Temperature | solvent rinse | Solvent | 1 | 2 | 3 | Average |
| 1 | Example 1 + | No Bake | 2 min | PGMEA | 31 | 32 | 31 | 31 |
| 2 | 20% TPnB | | | MIBC | 118 | 72 | 438 | 209 |
| 3 | | | | Acetone | 41 | 39 | 41 | 40 |
| 4 | | | | Cyclo-Hexanone | 183 | 204 | 339 | 242 |
| 5 | | | | PGPE | 62 | 34 | 37 | 44 |
| 6 | | 50° C. Bake | 2 min | PGMEA | 123 | 132 | 57 | 104 |
| 8 | | | 3 min | Acetone | 223 | 224 | 222 | 223 |
| 9 | | | 3 min | PGPE | 205 | 200 | 207 | 204 |
| 10 | | | 4 min | VT7000 | 282 | 281 | 279 | 281 |
| 11 | | 75° C. Bake | 2 min | PGMEA | 203 | 200 | 189 | 197 |

where PGPE is propylene glycol monopropyl ether and VT7000 is a blend of 70% gamma-Butyrolacetone and 30% n-butylacetate available from Ultra Pure Solutions, Inc. of Castroville, Calif.

From Table 3 it is observable that the onset insolubility temperature of Example 1+20% TPnB, that is, a titanium oxide composition Example 1 with the high boiling point solvent TPnB, has increased to 75° C. when the solvent PGMEA is used to remove the composition. In other words, 75° C. is the temperature at which PGMEA no longer removes the composition from the substrate.

TABLE 4

| | 1500 RPM 20 sec | | | | | | | |
|---|---|---|---|---|---|---|---|---|
| | | | Time wait | | Thickness (angstroms) | | | |
| | | Bake | before cleaning | | Site | Site | Site | |
| Slot | Material | Temperature | solvent rinse | Solvent | 1 | 2 | 3 | Average |
| 1 | Example 2 + | No Bake | 2 min | PGMEA | 40 | 29 | 31 | 33 |
| 2 | 20% TPnB | | | MIBC | 403 | 388 | 68 | 286 |
| 3 | | | | Acetone | 8 | 33 | 9 | 17 |
| 4 | | | | Cyclo-hexanone | 145 | 243 | 309 | 232 |
| 5 | | | | PGPE | 140 | 113 | 114 | 122 |
| 6 | | 50° C. Bake | 2 min | PGMEA | 32 | 47 | 35 | 38 |
| 8 | | | 3 min | Acetone | 23 | 15 | 13 | 17 |
| 9 | | | 3 min | PGPE | 33 | 39 | 80 | 51 |
| 10 | | | 4 min | VT7000 | 38 | 34 | 34 | 35 |
| 11 | | 75° C. Bake | 2 min | PGMEA | 39 | 29 | 26 | 31 |
| 12 | | | 1 min | Acetone | 26 | 29 | 18 | 24 |
| 13 | | | 2 min | PGPE | 251 | 293 | 252 | 265 |
| 14 | | | 1 min | VT7000 | 107 | 117 | 125 | 116 |
| 15 | | 100° C. Bake | 2 min | PGMEA | 281 | 324 | 292 | 299 |
| 16 | | | 2 min | Acetone | 263 | 306 | 320 | 296 |
| 17 | | | 2 min | VT7000 | 280 | 243 | 285 | 269 |

As illustrated in Table 4, the onset insolubility temperature for Example 2+20% TPnB, containing a composition stabilizer and the high boiling point solvent TPnB, has increased to 100° C. for PGMEA. Thus, Example 2+20% TPnB is easier to remove from a substrate using PGMEA than Example 1+20% TPnB and Examples 1 and 2.

TABLE 5

| | 1500 RPM 20 sec | | | | | | | |
|---|---|---|---|---|---|---|---|---|
| | | | Time wait | | Thickness (angstroms) | | | |
| | | Bake | before cleaning | | Site | Site | Site | |
| Slot | Material | Temperature | solvent rinse | Solvent | 1 | 2 | 3 | Average |
| 1 | Example 2-no | No Bake | 2 min | PGMEA | 15 | 20 | 25 | 20 |
| 2 | acid-no water + | | | Acetone | 25 | 32 | 35 | 31 |
| 3 | 3% TPnB | 50° C. | 2 min | PGMEA | 234 | 245 | 237 | 239 |
| 4 | | | 2 min | Acetone | 220 | 215 | 245 | 227 |

As illustrated in Table 5, the onset insolubility temperature for Example 2−no acid−no water+3% TPnB is 50° C. for PGMEA.

TABLE 6

| | 1500 RPM 20 sec | | | | | | | |
|---|---|---|---|---|---|---|---|---|
| | | | Time wait | | Thickness (angstroms) | | | |
| | | Bake | before cleaning | | Site | Site | Site | |
| Slot | Material | Temperature | solvent rinse | Solvent | 1 | 2 | 3 | Average |
| 1 | Example 2-no | No Bake | 2 min | PGMEA | 10 | 15 | 17 | 14 |
| 2 | water + acetic | | | Acetone | 21 | 25 | 27 | 24 |
| 3 | acid + 3% TPnB | 50° C. | 2 min | PGMEA | 30 | 35 | 32 | 32 |
| 4 | | | 2 min | Acetone | 35 | 45 | 47 | 42 |
| 5 | | 75° C. | 2 min | PGMEA | 251 | 267 | 258 | 259 |
| 6 | | | 2 min | Acetone | 262 | 245 | 289 | 265 |

As illustrated in Table 6, the onset insolubility temperature for Example 2−no water+acetic acid+3% TPnB is 75° C. for PGMEA.

TABLE 7

| | 1500 RPM 20 sec | | | | | | | |
|---|---|---|---|---|---|---|---|---|
| | | | Time wait | | Thickness (angstroms) | | | |
| | | Bake | before cleaning | | Site | Site | Site | |
| Slot | Material | temperature | solvent rinse | Solvent | 1 | 2 | 3 | Average |
| 1 | Example 2 + | no bake | 2 min | PGMEA | 35 | 40 | 41 | 39 |
| 2 | 3% TPnB | | | MIBC | 40 | 35 | 38 | 38 |
| 3 | | | 2 min | Acetone | 36 | 39 | 41 | 39 |
| 4 | | 50° C. | 2 min | PGMEA | 111 | 97 | 105 | 104 |
| 5 | | | 2 min | MIBC | 110 | 105 | 100 | 105 |
| 6 | | | 2 min | Acetone | 160 | 134 | 145 | 146 |
| 7 | | 75° C. | 2 min | PGMEA | 266 | 277 | 285 | 276 |
| 8 | | | 2 min | MIBC | 281 | 256 | 267 | 268 |
| 9 | | | 2 min | Acetone | 281 | 279 | 265 | 275 |

As illustrated in Table 7, the onset insolubility temperature for Example 2+3% TPnB is 75° C. for PGMEA.

TABLE 8

| | 1500 RPM 20 sec | | | | | | | |
|---|---|---|---|---|---|---|---|---|
| | | | Time wait | | Thickness (angstroms) | | | |
| | | Bake | before cleaning | | Site | Site | Site | |
| Slot | Material | temperature | solvent rinse | Solvent | 1 | 2 | 3 | Average |
| 1 | Example 2-no | no bake | 2 min | PGMEA | 34 | 36 | 41 | 37 |
| 2 | acid + 3% TPnB | | | MIBC | 35 | 36 | 38 | 36 |
| 3 | | | 2 min | Acetone | 34 | 35 | 37 | 35 |
| 4 | | 50° C. | 2 min | PGMEA | 49 | 50 | 53 | 51 |
| 5 | | | 2 min | MIBC | 91 | 95 | 93 | 93 |
| 6 | | | 2 min | Acetone | 80 | 75 | 77 | 77 |
| 7 | | 75° C. | 2 min | PGMEA | 260 | 259 | 234 | 251 |
| 8 | | | 2 min | MIBC | 245 | 250 | 256 | 250 |
| 9 | | | 2 min | Acetone | 278 | 280 | 269 | 276 |

As illustrated in Table 8, the onset insolubility temperature for Example 2−no acid+3% TPnB is 75° C. for PGMEA.

TABLE 9

| | | Ti % |
|---|---|---|
| | | residue after removal |
| | | with PGMEA (Atomic |
| Material | Substrate | Concentrations) |
| Example 1 | Si Wafer | 5.5 |
| Example 2 + 25% TPnB | Si Wafer | 5.3 |
| Example 2 − no acid-no | Si Wafer | 2.3 |
| water + 16% Acac + | HMDS primed wafer | — |
| 25% DPnP | | |

Table 9 demonstrates the amount of titanium residue from a liquid titanium oxide composition remaining on a wafer after being treated with PGMEA. The amount removed was measured using x-ray photoelectron spectroscopy (XPS). The “HMDS primed wafer” was a wafer treated with hexamethydisilazane. As illustrated in Table 9, Example 2−no acid−no water+16% Acac+25% DPnP demonstrates better removal with PGMEA compared to Example 1 and Example 2+25% TPnB with no Ti detected on the HMDS primed wafer.

Accordingly, a liquid titanium oxide composition is provided. In one embodiment, the titanium oxide composition is formed such that cross-linking during formation of the titanium oxide is inhibited. In this regard, the liquid titanium oxide composition may be formed substantially without water. In addition, or alternatively, the composition may be formed substantially without acid. In addition or alternatively, the composition may include a composition stabilizer. In another embodiment, the titanium oxide composition comprises a high boiling point solvent that has a boiling point in the range of from 140° C. to about 400° C. The high boiling point solvent increases the onset insolubility temperature such that the titanium oxide composition is more soluble in a cleaning solvent used to remove titanium oxide residue.

While at least one exemplary embodiment has been presented in the foregoing detailed description of the invention, it should be appreciated that a vast number of variations exist. It should also be appreciated that the exemplary embodiment or exemplary embodiments are only examples, and are not intended to limit the scope, applicability, or configuration of the invention in any way. Rather, the foregoing detailed description will provide those skilled in the art with a convenient road map for implementing an exemplary embodiment of the invention. It being understood that various changes may be made in the function and arrangement of elements described in an exemplary embodiment without departing from the scope of the invention as set forth in the appended claims.

1. A liquid titanium oxide composition comprising:
a solvent system;
an organotitanate; and
a high boiling point solvent having a boiling point in a range of about 140° C. to about 400° C.

2. The liquid titanium oxide composition of claim 1, wherein an onset insolubility temperature of the liquid titanium oxide composition, when spin coated onto a silicon substrate and subjected to PGMEA, is higher than an onset insolubility temperature of the same liquid titanium oxide composition without the high boiling point solvent when spin coated onto a comparable silicon substrate and subjected to PGMEA.

3. The liquid titanium oxide composition of claim 1, wherein the organotitanate comprises a titanium alkoxide.

4. The liquid titanium oxide composition of claim 1, wherein the organotitanate comprises a titanium-oxygen backbone polymer.

5. The liquid titanium oxide composition of claim 1, wherein the solvent system comprises an alcohol.

6. The liquid titanium oxide composition of claim 1, wherein the solvent system comprises water.

7. The liquid titanium oxide composition of claim 1, wherein the liquid titanium oxide composition comprises substantially no water.

8. The liquid titanium oxide composition of claim 1, wherein the liquid titanium oxide composition comprises substantially no acid.

9. The liquid titanium oxide composition of claim 1, wherein the organotitanate has a formula Ti(OR)₄, where each R is not necessarily the same and R is an alkyl radical having 1 to 6 carbons or R is an alkylene oxide.

10. The liquid titanium oxide composition of claim 9, wherein the organotitanate comprises tetraisopropyl titanate (TIPO), tetraethyl titanate, tetrapropyl titanate, tetrabutyl titanate, tetraisobutyl titranate, tetra-tert-butyl titanate, tetrahexyl titanate, titanium (polyethylene oxide) triisopropoxide, titanium diisopropoxide (bis-2,4-pentanedionate), or mixtures thereof.

11. The liquid titanium oxide composition of claim 1, further comprising a composition stabilizer.

12. The liquid titanium oxide composition of claim 11, wherein the composition stabilizer comprises 2,4-pentanedione, 3,3-dimethyl-2,4-pentanedione, 3-methy-2,4-pentanedione ethylacetoacetate, diethyl malonate, diethyl malate, ethylene diamine tetra-acetic acid, oxalic acid, oxamic acid, octanoic acid, oleic acid, dodecylcarboxylic acid, perfluorooctanoic acid, ethyl lactate, butylated hydroxytoluene, 1,3-propane diol, methyl pyruvate, or mixtures thereof.

13. The liquid titanium oxide composition of claim 1, wherein the high boiling point solvent comprises tripropylene glycol methyl ether, dipropylene glycol n-propyl ether, dipropylene glycol butyl ether, tripropylene glycol n-butyl ether, carbitol, hexyl carbitol, methoxytriglycol, methyl carbitol, butyl cellosolve, butyl cellosolve acetate, butyl carbitol acetate, diethylene glycol phenyl ether, or mixtures thereof.

14. The liquid titanium oxide composition of claim 1, wherein the liquid titanium oxide composition has a viscosity no greater than about 5 cP.

15. A method for forming a liquid titanium oxide composition, the method comprising the steps of:
adding an organotitanate to a solvent system to form a mixture, wherein the organotitanate has a formula: Ti(OR)₄, where each R can be different and R is an alkyl radical having 1 to 6 carbons or R is an alkylene oxide;
adding a high boiling point solvent to the mixture, the high boiling point solvent having a boiling point in a range of from about 140° C. to about 400° C.; and
mixing the high boiling point solvent and the mixture.

16. The liquid titanium oxide composition of claim 4, wherein the titanium-oxygen backbone polymer comprises hydroxy pendant groups, alkoxy pendant groups, acetonate pendant groups, or combinations thereof.

17. The liquid titanium oxide composition of claim 4, wherein the titanium-oxygen backbone polymer has a molecular weight in the range of from about 200 to about 10 million Daltons.

18. The liquid titanium oxide composition of claim 1, wherein the solvent system comprises an ether, an ester, an aldehyde, a carboxylic acid, a glycol ether, a polyglycol ether, a fluorinated alkane, a chlorinated alkane, and mixtures thereof.

19. The liquid titanium oxide composition of claim 1, wherein the solvent system comprises water in an amount of from about 0.05 to about 3.0 moles/moles of titanium in the organotitanate.

20. The liquid titanium oxide composition of claim 1, wherein the organotitanate has a formula Ti(OR)₄, where each R is not necessarily the same and R is an alkyl radical having 1 to 6 carbons or R is an alkylene oxide.
